(19) United States
(12) Patent Application Publication
(10) Pub. No.: US 2025/0013158 A1
(43) Pub. Date: Jan. 9, 2025

(54) SURROUNDING PATTERN AND PROCESS AWARE METROLOGY

(71) Applicant: ASML NETHERLANDS B.V., Veldhoven (NL)

(72) Inventors: Huaichen ZHANG, Eindhoven (NL); Ruben Cornelis MAAS, Houten (NL); Syam Parayil VENUGOPALAN, Eindhoven (NL); Jan Wouter BIJLSMA, Veldhoven (NL)

(73) Assignee: ASML NETHERLANDS B.V., Veldhoven (NL)

(21) Appl. No.: 18/712,671

(22) PCT Filed: Nov. 22, 2022
(86) PCT No.: PCT/EP2022/082791

§ 371 Date: May 22, 2024

(30) Foreign Application Priority Data
Dec. 9, 2021 (EP) 21213572.7

(51) Int. Cl. G03F 7/00

(52) U.S. Cl. CPC G03F 7/70683; G03F 7/706839

(57) ABSTRACT

A method and system for designing a mark for use in imaging of a pattern on a substrate using a lithographic process in a lithographic apparatus. The method includes obtaining a mark construction, obtaining a spatial variation of a geometric parameter associated with the mark construction, and determining a geometry design of individual patterns of a mark based on the spatial variation and a spatial location of the mark.

### CROSS-REFERENCE TO RELATED APPLICATIONS

This application claims priority of EP application 21213572.7 which was filed on Dec. 9, 2021 and which is incorporated herein in its entirety by reference.

### TECHNICAL FIELD

The description herein relates to metrology of a product in a lithographic process, and more particularly to designing a metrology target.

### BACKGROUND

A lithographic apparatus is a machine constructed to apply a desired pattern onto a substrate. A lithographic apparatus can be used, for example, in the manufacture of integrated circuits (ICs). A lithographic apparatus may, for example, project a pattern (also often referred to as “design layout” or “design”) of a patterning device (e.g., a mask) onto a layer of radiation-sensitive material (resist) provided on a substrate (e.g., a wafer). This manufacturing process may be referred to as a patterning process or a lithographic process. For example, an IC chip in a smart phone, can be as small as a person's thumbnail, and may include over 2 billion transistors. Making an IC is a complex and time-consuming process, with circuit components in different layers and including hundreds of individual steps. Errors in even one step have the potential to result in problems with the final IC and can cause device failure. High process yield and high wafer throughput can be impacted by the presence of defects, especially if operator intervention is required for reviewing the defects.

Metrology processes are used at various steps during a patterning process to monitor and/or control the process. For example, metrology processes are used to measure one or more characteristics of a substrate, such as a relative location (e.g., registration, overlay, alignment, etc.) or dimension (e.g., line width, critical dimension (CD), thickness, etc.) of features formed on the substrate during the patterning process, such that, for example, the performance of the patterning process can be determined from the one or more characteristics. If the one or more characteristics are unacceptable (e.g., out of a predetermined range for the characteristic(s)), one or more variables of the patterning process may be designed or altered, e.g., based on the measurements of the one or more characteristics, such that substrates manufactured by the patterning process have an acceptable characteristic(s).

### SUMMARY

In some embodiments, there is provided a non-transitory computer readable medium having instructions that, when executed by a computer, cause the computer to execute a method for a mark design for use in imaging of a pattern on a substrate using a lithographic process in a lithographic apparatus. The method includes: obtaining a mark construction; obtaining a spatial variation of a geometric parameter associated with the mark construction, wherein the spatial variation is associated with a lithographic process; and determining geometry design of individual patterns of a mark based on the spatial variation of the mark.

In some embodiments, there is provided a method for a mark design for use in imaging of a pattern on a substrate using a lithographic process in a lithographic apparatus. The method includes: obtaining a mark construction; obtaining a spatial variation of a geometric parameter associated with the mark construction, wherein the spatial variation is associated with a lithographic process; and determining geometry design of individual patterns of a mark based on the spatial variation of the mark.

In some embodiments, there is provided an apparatus for a mark design for use in imaging of a pattern on a substrate using a lithographic process in a lithographic apparatus. The apparatus includes: a memory storing a set of instructions; and a processor configured to execute the set of instructions to cause the apparatus to perform a method of: obtaining a mark construction; obtaining a spatial variation of a geometric parameter associated with the mark construction, wherein the spatial variation is associated with a lithographic process; and determining geometry design of individual patterns of a mark based on the spatial variation of the mark.

### BRIEF DESCRIPTION OF THE DRAWINGS

FIG. 1 is a schematic diagram of a lithographic projection apparatus, according to an embodiment.

FIG. 2 schematically depicts an embodiment of a lithographic cell or cluster.

FIG. 3A is schematic diagram of a measurement apparatus (e.g., metrology apparatus) for use in measuring targets using a first pair of illumination apertures providing certain illumination modes, in accordance with an embodiment.

FIG. 3B is a schematic detail of a diffraction spectrum of a target for a given direction of illumination, in accordance with an embodiment.

FIG. 3C is a schematic illustration of a second pair of illumination apertures providing further illumination modes in using a measurement apparatus for diffraction based overlay measurements, in accordance with an embodiment.

FIG. 3D is a schematic illustration of a third pair of illumination apertures combining the first and second pairs of apertures providing further illumination modes in using a measurement apparatus for diffraction based overlay measurements, in accordance with an embodiment.

FIG. 3E depicts a form of multiple periodic structure (e.g., multiple grating) target and an outline of a measurement spot on a substrate, in accordance with an embodiment.

FIG. 3F depicts an image of the target of FIG. 3E obtained in the apparatus of FIG. 3A.

FIGS. 4A, 4B and 4C comprise flowcharts of different aspects of an exemplary target design method usable in designing targets disclosed herein, in accordance with an embodiment.

FIG. 5 is a block diagram of a system for designing a mark based on the local geometry of the mark, in accordance with an embodiment.

FIGS. 6A and 6B are flows diagram a method for designing a mark based on the local geometry of the mark, in accordance with an embodiment.

FIG. 7 shows an example dummification process of marks, in accordance with an embodiment.

FIG. 8 is a block diagram that illustrates a computer system which can assist in implementing the systems and methods disclosed herein.

FIG. 9 shows a flow for a lithographic process or patterning simulation method, according to an embodiment.

### DETAILED DESCRIPTION

Metrology is a process used to measure one or more characteristics of a substrate, such as a relative location (e.g., registration, overlay, alignment, etc.) or dimension (e.g., line width, critical dimension (CD), thickness, etc.) of features formed on the substrate during the patterning process, such that, for example, the performance of the patterning process can be determined from the one or more characteristics. A metrology target (also referred to as “metrology mark” or “mark”), such as an overlay (OVL) mark, an alignment mark, or another mark (fiducial), can be used in obtaining the measurements. A metrology mark is constructed or designed based on one or more lithographic process parameters. The metrology mark may have a number of individual patterns in it (e.g., a periodic structure, such as a grating). Simulation models may be used in designing or optimizing a metrology mark, or in determining a measurement performance (e.g., accuracy of the measurements obtained using the metrology mark) of the metrology mark. However, conventional methods of designing the metrology mark are inefficient. For example, conventional methods use nominal geometric parameters (e.g., for the metrology mark as a whole or for only a portion of the metrology mark), without considering intra-mark geometry variations or surrounding patterns (e.g., patterns within a specified proximity of the metrology mark), in optimizing the metrology mark. For example, in the metrology mark simulated by the conventional methods, it is assumed that each individual pattern may have the same geometric parameter, such as a sidewall angle, etch depth, CD, pitch, etc. However, in practice there are variations in the geometric parameters of the individual patterns within the mark. The variation may result from one or more fabrication processes in manufacturing the metrology mark, for example deposition, etching, CMP, photo-lithography, etc. The variation of geometric parameters of the individual patterns, or a presence or absence of surrounding patterns, may have a significant bearing on the measurement performance of the mark. Accordingly, metrology marks that are designed without such considerations may have a non-optimal design, which may result in obtaining inaccurate measurements, which in turn may impact a yield of the manufacturing process.

According to the present disclosure, a mark (e.g., metrology mark) is designed (or optimized) by considering a local geometry of the mark (e.g., spatial variations of a geometric parameter of each of the individual patterns of the mark). The designing method may also consider a spatial location of the mark within a target design layout (e.g., full chip design layout), or a presence or absence of surrounding patterns of the mark. In some embodiments, a simulation model is used to design the mark, simulate a measurement performance of the mark, and optimize the mark based on the measurement performance. For example, a simulation model that simulates a target design layout (e.g., for an entire Integrated circuit, also referred to as “full-chip design layout”) based on an input target design layout and process parameters of a lithographic process is used to generate the target design layout. The metrology marks in the simulated full-chip design layout, however, may not be optimized based on the intra-mark variations (e.g., spatial variation of the geometric parameters of individual patterns that make up the mark) since they are not considered by the simulation model for optimization of the full-chip design layout. Accordingly, a coarse grid having a metrology mark to be optimized is identified in the target design layout, and the coarse grid is interpolated to extract a spatial variation of the geometric parameters of each of the individual patterns of the metrology mark. The metrology mark is reconstructed based on at least one of the extracted geometrical parameters, a spatial location of the metrology mark in the target design layout, or surrounding patterns of the metrology mark. A measurement simulation model may simulate measurement parameters (e.g., optical measurement parameters) obtained using the reconstructed metrology mark (e.g., that would have been obtained using a metrology tool). In some embodiments, key performance indicators (KPIs) that are indicative of the measurement performance is computed based on the simulated measurement parameters, and the metrology mark is iteratively optimized until the KPIs are optimized. In some embodiments, adjusting the metrology mark includes adjusting geometric design (e.g., a critical dimension, pitch, or sub-segmentation) of the individual patterns of the mark.

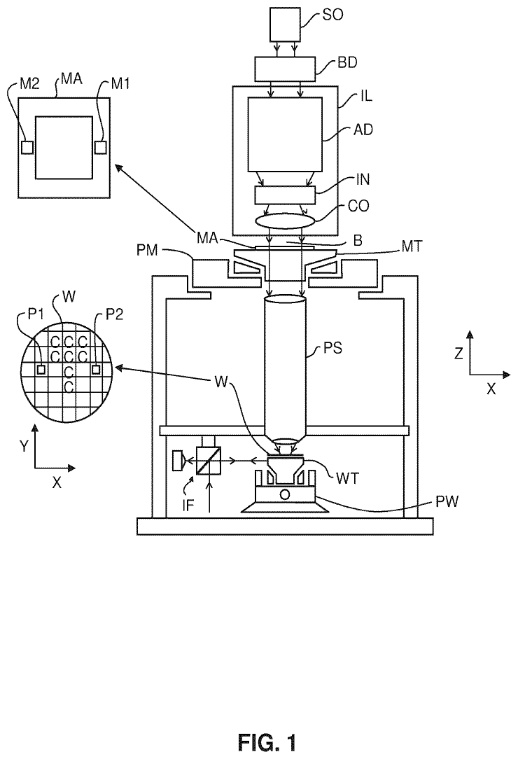

FIG. 1 schematically depicts a lithographic apparatus in accordance with one or more embodiments. The apparatus comprises:
an illumination system (illuminator) IL configured to condition a radiation beam B (e.g., UV radiation or DUV radiation);
a first object holder or a support structure (e.g., a mask table) MT constructed to hold a patterning device (e.g., a mask) MA and connected to a first positioner PM configured to accurately position the patterning device in accordance with certain parameters;
a second object holder such as a substrate holder or substrate table (e.g., a wafer table) WT constructed to hold a substrate (e.g., a resist coated wafer) W and connected to a second positioner PW configured to accurately position the substrate in accordance with certain parameters; and
a projection system (e.g., a refractive projection lens system) PS configured to project a pattern imparted to the radiation beam B by patterning device MA onto a target portion C (e.g., comprising one or more dies) of the substrate W.

The illumination system may include various types of optical components, such as refractive, reflective, magnetic, electromagnetic, electrostatic or other types of optical components, or any combination thereof, for directing, shaping, or controlling radiation.

The support structure holds the patterning device in a manner that depends on the orientation of the patterning device, the design of the lithographic apparatus, and other conditions, such as for example whether or not the patterning device is held in a vacuum environment. The support structure can use mechanical, vacuum, electrostatic or other clamping techniques to hold the patterning device. The support structure may be a frame or a table, for example, which may be fixed or movable as required. The support structure may ensure that the patterning device is at a desired position, for example with respect to the projection system. Any use of the terms “reticle” or “mask” herein may be considered synonymous with the more general term “patterning device.”

The term “patterning device” used herein should be broadly interpreted as referring to any device that can be used to impart a radiation beam with a pattern in its cross-section such as to create a pattern in a target portion of the substrate. It should be noted that the pattern imparted to the radiation beam may not exactly correspond to the desired pattern in the target portion of the substrate, for example if the pattern includes phase-shifting features or so called assist features. Generally, the pattern imparted to the radiation beam will correspond to a particular functional layer in a device being created in the target portion, such as an integrated circuit.

The patterning device may be transmissive or reflective. Examples of patterning devices include masks, programmable mirror arrays, and programmable LCD panels. Masks are well known in lithography, and include mask types such as binary, alternating phase-shift, and attenuated phase-shift, as well as various hybrid mask types. An example of a programmable mirror array employs a matrix arrangement of small mirrors, each of which can be individually tilted so as to reflect an incoming radiation beam in different directions. The tilted mirrors impart a pattern in a radiation beam which is reflected by the mirror matrix.

The term “projection system” used herein should be broadly interpreted as encompassing any type of projection system, including refractive, reflective, catadioptric, magnetic, electromagnetic and electrostatic optical systems, or any combination thereof, as appropriate for the exposure radiation being used, or for other factors such as the use of an immersion liquid or the use of a vacuum. Any use of the term “projection lens” herein may be considered as synonymous with the more general term “projection system”.

As here depicted, the apparatus is of a transmissive type (e.g., employing a transmissive mask). Alternatively, the apparatus may be of a reflective type (e.g., employing a programmable mirror array of a type as referred to above, or employing a reflective mask).

The lithographic apparatus may be of a type having two (dual stage) or more substrate tables (and/or two or more support structures). In such “multiple stage” machines the additional tables/support structure may be used in parallel, or preparatory steps may be carried out on one or more tables/support structure while one or more other tables/support structures are being used for exposure.

Referring to FIG. 1, the illuminator IL receives a radiation beam from a radiation source SO. The source and the lithographic apparatus may be separate entities, for example when the source is an excimer laser. In such cases, the source is not considered to form part of the lithographic apparatus and the radiation beam is passed from the source SO to the illuminator IL with the aid of a beam delivery system BD comprising, for example, suitable directing mirrors and/or a beam expander. In other cases, the source may be an integral part of the lithographic apparatus, for example when the source is a mercury lamp. The source SO and the illuminator IL, together with the beam delivery system BD if required, may be referred to as a radiation system.

The illuminator IL may comprise an adjuster AD configured to adjust the angular intensity distribution of the radiation beam. Generally, at least the outer and/or inner radial extent (commonly referred to as σ-outer and σ-inner, respectively) of the intensity distribution in a pupil plane of the illuminator can be adjusted. In addition, the illuminator IL may comprise various other components, such as an integrator IN and a condenser CO. The illuminator may be used to condition the radiation beam, to have a desired uniformity and intensity distribution in its cross section.

The radiation beam B is incident on the patterning device (e.g., mask) MA, which is held on the support structure (e.g., mask table) MT, and is patterned by the patterning device. Having traversed the patterning device MA, the radiation beam B passes through the projection system PS, which focuses the beam onto a target portion C of the substrate W. With the aid of the second positioner PW and position sensor IF (e.g., an interferometric device, linear encoder or capacitive sensor), the substrate table WT can be moved accurately, e.g., so as to position different target portions C in the path of the radiation beam B. Similarly, the first positioner PM and another position sensor (which is not explicitly depicted in FIG. 1) can be used to accurately position the patterning device MA with respect to the path of the radiation beam B, e.g., after mechanical retrieval from a mask library, or during a scan. In general, movement of the support structure MT may be realized with the aid of a long-stroke module (coarse positioning) and a short-stroke module (fine positioning), which form part of the first positioner PM. Similarly, movement of the substrate table WT may be realized using a long-stroke module and a short-stroke module, which form part of the second positioner PW. In the case of a stepper (as opposed to a scanner) the support structure MT may be connected to a short-stroke actuator only, or may be fixed. Patterning device MA and substrate W may be aligned using patterning device alignment marks M1, M2 and substrate alignment marks P1, P2. Although the substrate alignment marks as illustrated occupy dedicated target portions, they may be located in spaces between target portions (these are known as scribe-lane alignment marks). Similarly, in situations in which more than one die is provided on the patterning device MA, the patterning device alignment marks may be located between the dies.

The depicted apparatus could be used in at least one of the following modes:

1. In step mode, the support structure MT and the substrate table WT are kept essentially stationary, while an entire pattern imparted to the radiation beam is projected onto a target portion C at one time (i.e., a single static exposure). The substrate table WT is then shifted in the X and/or Y direction so that a different target portion C can be exposed. In step mode, the maximum size of the exposure field limits the size of the target portion C imaged in a single static exposure.

2. In scan mode, the support structure MT and the substrate table WT are scanned synchronously while a pattern imparted to the radiation beam is projected onto a target portion C (i.e., a single dynamic exposure). The velocity and direction of the substrate table WT relative to the support structure MT may be determined by the (de-)magnification and image reversal characteristics of the projection system PS. In scan mode, the maximum size of the exposure field limits the width (in the non-scanning direction) of the target portion in a single dynamic exposure, whereas the length of the scanning motion determines the height (in the scanning direction) of the target portion.

3. In another mode, the support structure MT is kept essentially stationary holding a programmable patterning device, and the substrate table WT is moved or scanned while a pattern imparted to the radiation beam is projected onto a target portion C. In this mode, generally a pulsed radiation source is employed and the programmable patterning device is updated as required after each movement of the substrate table WT or in between successive radiation pulses during a scan. This mode of operation can be readily applied to maskless lithography that utilizes programmable patterning device, such as a programmable mirror array of a type as referred to above.

Combinations and/or variations on the above described modes of use or entirely different modes of use may also be employed.

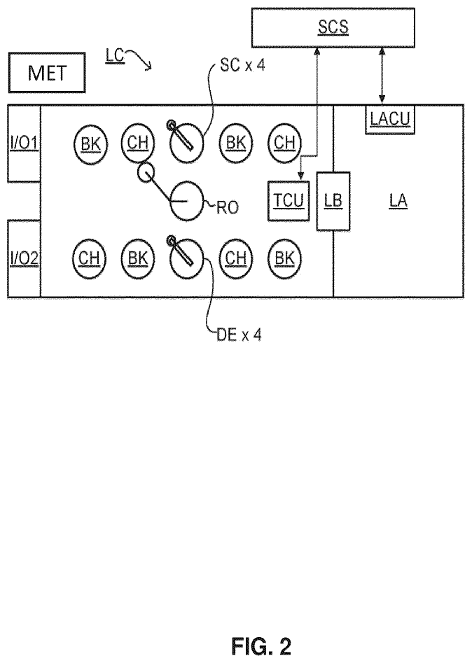

As shown in FIG. 2, the lithographic apparatus LA may form part of a lithographic cell LC, also sometimes referred to a lithocell or cluster, which also includes apparatuses to perform pre- and post-exposure processes on a substrate. Conventionally these include one or more spin coaters SC to deposit one or more resist layers, one or more developers DE to develop exposed resist, one or more chill plates CH and/or one or more bake plates BK. A substrate handler, or robot, RO picks up one or more substrates from input/output port I/O1, I/O2, moves them between the different process apparatuses and delivers them to the loading bay LB of the lithographic apparatus. These apparatuses, which are often collectively referred to as the track, are under the control of a track control unit TCU which is itself controlled by the supervisory control system SCS, which also controls the lithographic apparatus via lithography control unit LACU. Thus, the different apparatuses can be operated to maximize throughput and processing efficiency.

In order that a substrate that is exposed by the lithographic apparatus is exposed correctly and consistently and/or in order to monitor a part of the patterning process (e.g., a device manufacturing process) that includes at least one pattern transfer step (e.g., an optical lithography step), it is desirable to inspect a substrate or other object to measure or determine one or more properties such as alignment, overlay (which can be, for example, between structures in overlying layers or between structures in a same layer that have been provided separately to the layer by, for example, a double patterning process), line thickness, critical dimension (CD), focus offset, a material property, etc. Accordingly, a manufacturing facility in which lithocell LC is located also typically includes a metrology system MET which measures some or all of the substrates W that have been processed in the lithocell or other objects in the lithocell. The metrology system MET may be part of the lithocell LC, for example it may be part of the lithographic apparatus LA (such as alignment sensor AS).

The one or more measured parameters may include, for example, overlay between successive layers formed in or on the patterned substrate, critical dimension (CD) (e.g., critical linewidth) of, for example, features formed in or on the patterned substrate, focus or focus error of an optical lithography step, dose or dose error of an optical lithography step, optical aberrations of an optical lithography step, etc. This measurement may be performed on a target of the product substrate itself and/or on a dedicated metrology target provided on the substrate. The measurement can be performed after-development of a resist but before etching or can be performed after-etch.

There are various techniques for making measurements of the structures formed in the patterning process, including the use of a scanning electron microscope, an image-based measurement tool and/or various specialized tools. As discussed above, a fast and non-invasive form of specialized metrology tool is one in which a beam of radiation is directed onto a target on the surface of the substrate and properties of the scattered (diffracted/reflected) beam are measured. By evaluating one or more properties of the radiation scattered by the substrate, one or more properties of the substrate can be determined. This may be termed diffraction-based metrology. One such application of this diffraction-based metrology is in the measurement of feature asymmetry within a target. This can be used as a measure of overlay, for example, but other applications are also known. For example, asymmetry can be measured by comparing opposite parts of the diffraction spectrum (for example, comparing the −1st and +1st orders in the diffraction spectrum of a periodic grating). This can be done as described above and as described, for example, in U.S. patent application publication US 2006-0066855, which is incorporated herein in its entirety by reference. Another application of diffraction-based metrology is in the measurement of feature width (CD) within a target. Such techniques can use the apparatus and methods described hereafter.

Thus, in a device fabrication process (e.g., a patterning process or a lithography process), a substrate or other objects may be subjected to various types of measurement during or after the process. The measurement may determine whether a particular substrate is defective, may establish adjustments to the process and apparatuses used in the process (e.g., aligning two layers on the substrate or aligning the patterning device to the substrate), may measure the performance of the process and the apparatuses, or may be for other purposes. Examples of measurement include optical imaging (e.g., optical microscope), non-imaging optical measurement (e.g., measurement based on diffraction, mechanical measurement (e.g., profiling using a stylus, atomic force microscopy (AFM)), and/or non-optical imaging (e.g., scanning electron microscopy (SEM)). The alignment system, as described in U.S. Pat. No. 6,961,116, which is incorporated by reference herein in its entirety, employs a self-referencing interferometer that produces two overlapping and relatively rotated images of an alignment marker, detects intensities in a pupil plane where Fourier transforms of the images are caused to interfere, and extracts the positional information from the phase difference between diffraction orders of the two images which manifests as intensity variations in the interfered orders.

Metrology results may be provided directly or indirectly to the supervisory control system SCS. If an error is detected, an adjustment may be made to exposure of a subsequent substrate (especially if the inspection can be done soon and fast enough that one or more other substrates of the batch are still to be exposed) and/or to subsequent exposure of the exposed substrate. Also, an already exposed substrate may be stripped and reworked to improve yield, or discarded, thereby avoiding performing further processing on a substrate known to be faulty. In a case where only some target portions of a substrate are faulty, further exposures may be performed only on those target portions which are good.

Within a metrology system MET, a metrology apparatus is used to determine one or more properties of the substrate, and in particular, how one or more properties of different substrates vary or different layers of the same substrate vary from layer to layer. As noted above, the metrology apparatus may be integrated into the lithographic apparatus LA or the lithocell LC or may be a stand-alone device.

To enable the metrology, one or more metrology targets (also referred to as “target,” “metrology mark,” or “mark”) can be provided on the substrate. In an embodiment, the target is specially designed and may comprise a periodic structure. In an embodiment, the target is a part of a device pattern, e.g., a periodic structure of the device pattern. In an embodiment, the device pattern is a periodic structure of a memory device (e.g., a Bipolar Transistor (BPT), a Bit Line Contact (BLC), etc. structure).

In an embodiment, the target on a substrate may comprise one or more 1-D periodic structures (e.g., gratings), which are printed such that after development, the periodic structural features are formed of solid resist lines. In an embodiment, the target may comprise one or more 2-D periodic structures (e.g., gratings), which are printed such that after development, the one or more periodic structures are formed of solid resist pillars or vias in the resist. The bars, pillars or vias may alternatively be etched into the substrate (e.g., into one or more layers on the substrate).

In an embodiment, one of the parameters of interest of a patterning process is overlay. Overlay can be measured using dark field scatterometry in which the zeroth order of diffraction (corresponding to a specular reflection) is blocked, and only higher orders processed. Examples of dark field metrology can be found in PCT patent application publication nos. WO 2009/078708 and WO 2009/106279, which are hereby incorporated in their entirety by reference. Further developments of the technique have been described in U.S. patent application publications US2011-0027704, US2011-0043791 and US2012-0242970, which are hereby incorporated in their entirety by reference. Diffraction-based overlay using dark-field detection of the diffraction orders enables overlay measurements on smaller targets. These targets can be smaller than the illumination spot and may be surrounded by device product structures on a substrate. In an embodiment, multiple targets can be measured in one radiation capture.

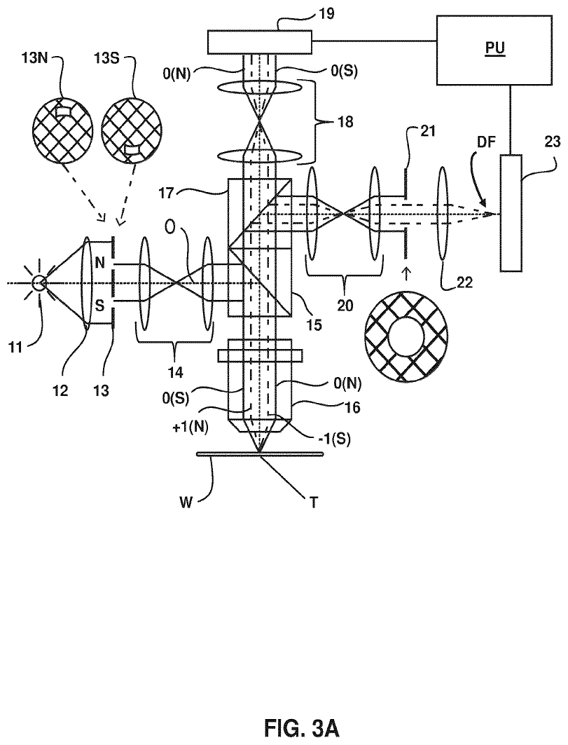

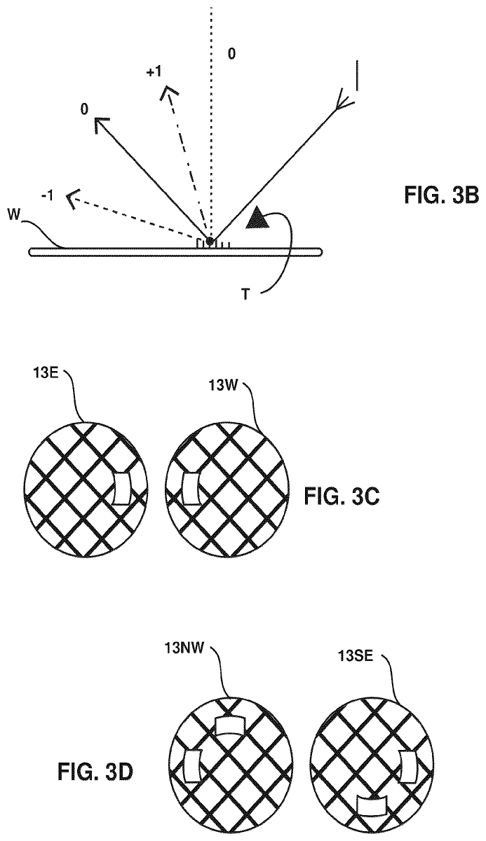

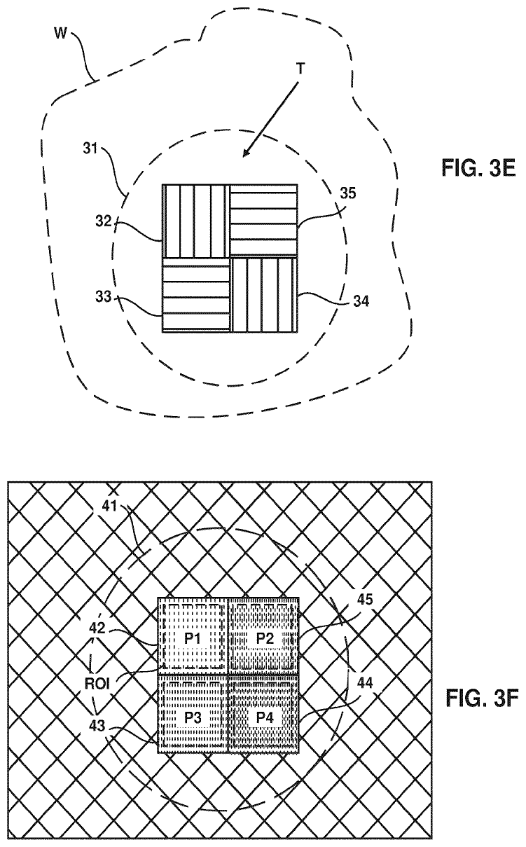

A metrology apparatus suitable for use in embodiments to measure, e.g., overlay is schematically shown in FIG. 3A. A target T (comprising a periodic structure such as a grating) and diffracted rays are illustrated in more detail in FIG. 3B. The metrology apparatus may be a stand-alone device or incorporated in either the lithographic apparatus LA, e.g., at the measurement station, or the lithographic cell LC. An optical axis, which has several branches throughout the apparatus, is represented by a dotted line O. In this apparatus, radiation emitted by an output 11 (e.g., a source such as a laser or a xenon lamp or an opening connected to a source) is directed onto substrate W via a prism 15 by an optical system comprising lenses 12, 14 and objective lens 16. These lenses are arranged in a double sequence of a 4F arrangement. A different lens arrangement can be used, provided that it still provides a substrate image onto a detector.

In an embodiment, the lens arrangement allows for access of an intermediate pupil-plane for spatial-frequency filtering. Therefore, the angular range at which the radiation is incident on the substrate can be selected by defining a spatial intensity distribution in a plane that presents the spatial spectrum of the substrate plane, here referred to as a (conjugate) pupil plane. In particular, this can be done, for example, by inserting an aperture plate 13 of suitable form between lenses 12 and 14, in a plane which is a back-projected image of the objective lens pupil plane. In the example illustrated, aperture plate 13 has different forms, labeled 13N and 13S, allowing different illumination modes to be selected. The illumination system in the present examples forms an off-axis illumination mode. In the first illumination mode, aperture plate 13N provides off-axis illumination from a direction designated, for the sake of description only, as ‘north’. In a second illumination mode, aperture plate 13S is used to provide similar illumination, but from an opposite direction, labeled ‘south’. Other modes of illumination are possible by using different apertures. The rest of the pupil plane is desirably dark as any unnecessary radiation outside the desired illumination mode may interfere with the desired measurement signals.

As shown in FIG. 3B, target T is placed with substrate W substantially normal to the optical axis O of objective lens 16. A ray of illumination I impinging on target T from an angle off the axis O gives rise to a zeroth order ray (solid line 0) and two first order rays (dot-chain line +1 and double dot-chain line −1). With an overfilled small target T, these rays are just one of many parallel rays covering the area of the substrate including metrology target T and other features. Since the aperture in plate 13 has a finite width (necessary to admit a useful quantity of radiation), the incident rays I will in fact occupy a range of angles, and the diffracted rays 0 and +1/−1 will be spread out somewhat. According to the point spread function of a small target, each order +1 and −1 will be further spread over a range of angles, not a single ideal ray as shown. Note that the periodic structure pitch and illumination angle can be designed or adjusted so that the first order rays entering the objective lens are closely aligned with the central optical axis. The rays illustrated in FIGS. 3A and 3B are shown somewhat off axis, purely to enable them to be more easily distinguished in the diagram. At least the 0 and +1 orders diffracted by the target on substrate W are collected by objective lens 16 and directed back through prism 15.

Returning to FIG. 3A, both the first and second illumination modes are illustrated, by designating diametrically opposite apertures labeled as north (N) and south(S). When the incident ray I is from the north side of the optical axis, that is when the first illumination mode is applied using aperture plate 13N, the +1 diffracted rays, which are labeled +1(N), enter the objective lens 16. In contrast, when the second illumination mode is applied using aperture plate 13S the −1 diffracted rays (labeled 1(S)) are the ones which enter the lens 16. Thus, in an embodiment, measurement results are obtained by measuring the target twice under certain conditions, e.g., after rotating the target or changing the illumination mode or changing the imaging mode to obtain separately the −1st and the +1st diffraction order intensities. Comparing these intensities for a given target provides a measurement of asymmetry in the target, and asymmetry in the target can be used as an indicator of a parameter of a lithography process, e.g., overlay. In the situation described above, the illumination mode is changed.

A beam splitter 17 divides the diffracted beams into two measurement branches. In a first measurement branch, optical system 18 forms a diffraction spectrum (pupil plane image) of the target on first sensor 19 (e.g., a CCD or CMOS sensor) using the zeroth and first order diffractive beams. Each diffraction order hits a different point on the sensor, so that image processing can compare and contrast orders. The pupil plane image captured by sensor 19 can be used for focusing the metrology apparatus and/or normalizing intensity measurements. The pupil plane image can also be used for other measurement purposes such as reconstruction, as described further hereafter.

In the second measurement branch, optical system 20, 22 forms an image of the target on the substrate W on sensor 23 (e.g., a CCD or CMOS sensor). In the second measurement branch, an aperture stop 21 is provided in a plane that is conjugate to the pupil-plane of the objective lens 16. Aperture stop 21 functions to block the zeroth order diffracted beam so that the image of the target formed on sensor 23 is formed from the −1 or +1 first order beam. Data regarding the images measured by sensors 19 and 23 are output to processor and controller PU, the function of which will depend on the particular type of measurements being performed. Note that the term ‘image’ is used in a broad sense. An image of the periodic structure features (e.g., grating lines) as such will not be formed, if only one of the −1 and +1 orders is present.

The particular forms of aperture plate 13 and stop 21 shown in FIG. 3A are purely examples. In another embodiment, on-axis illumination of the targets is used and an aperture stop with an off-axis aperture is used to pass substantially only one first order of diffracted radiation to the sensor. In yet other embodiments, 2nd, 3rd and higher order beams (not shown in FIG. 3A) can be used in measurements, instead of or in addition to the first order beams.

In order to make the illumination adaptable to these different types of measurement, the aperture plate 13 may comprise a number of aperture patterns formed around a disc, which rotates to bring a desired pattern into place. Note that aperture plate 13N or 13S are used to measure a periodic structure of a target oriented in one direction (X or Y depending on the set-up). For measurement of an orthogonal periodic structure, rotation of the target through 90° and 270° might be implemented. Different aperture plates are shown in FIGS. 3C and D. FIG. 3C illustrates two further types of off-axis illumination mode. In a first illumination mode of FIG. 3C, aperture plate 13E provides off-axis illumination from a direction designated, for the sake of description only, as ‘east’ relative to the ‘north’ previously described. In a second illumination mode of FIG. 3C, aperture plate 13W is used to provide similar illumination, but from an opposite direction, labeled ‘west’. FIG. 3D illustrates two further types of off-axis illumination mode. In a first illumination mode of FIG. 3D, aperture plate 13NW provides off-axis illumination from the directions designated ‘north’ and ‘west’ as previously described. In a second illumination mode, aperture plate 13SE is used to provide similar illumination, but from an opposite direction, labeled ‘south’ and ‘east’ as previously described. The use of these, and numerous other variations and applications of the apparatus are described in, for example, the prior published patent application publications mentioned above.

FIG. 3E depicts an example composite metrology target T formed on a substrate. The composite target comprises four periodic structures (in this case, gratings) 32, 33, 34, 35 positioned closely together. In an embodiment, the periodic structure layout may be made smaller than the measurement spot (i.e., the periodic structure layout is overfilled). Thus, in an embodiment, the periodic structures are positioned closely together enough so that they all are within a measurement spot 31 formed by the illumination beam of the metrology apparatus. In that case, the four periodic structures thus are all simultaneously illuminated and simultaneously imaged on sensors 19 and 23. In an example dedicated to overlay measurement, periodic structures 32, 33, 34, 35 are themselves composite periodic structures (e.g., composite gratings) formed by overlying periodic structures, i.e., periodic structures are patterned in different layers of the device formed on substrate W and such that at least one periodic structure in one layer overlays at least one periodic structure in a different layer. Such a target may have outer dimensions within 20 μm×20 μm or within 16 μm×16 μm. Further, all the periodic structures are used to measure overlay between a particular pair of layers. To facilitate a target being able to measure more than a single pair of layers, periodic structures 32, 33, 34, 35 may have differently biased overlay offsets in order to facilitate measurement of overlay between different layers in which the different parts of the composite periodic structures are formed. Thus, all the periodic structures for the target on the substrate would be used to measure one pair of layers and all the periodic structures for another same target on the substrate would be used to measure another pair of layers, wherein the different bias facilitates distinguishing between the layer pairs.

Returning to FIG. 3E, periodic structures 32, 33, 34, 35 may also differ in their orientation, as shown, so as to diffract incoming radiation in X and Y directions. In one example, periodic structures 32 and 34 are X-direction periodic structures with biases of +d, −d, respectively. Periodic structures 33 and 35 may be Y-direction periodic structures with offsets +d and −d respectively. While four periodic structures are illustrated, another embodiment may include a larger matrix to obtain desired accuracy. For example, a 3×3 array of nine composite periodic structures may have biases −4d, −3d, −2d, −d, 0, +d, +2d, +3d, +4d. Separate images of these periodic structures can be identified in an image captured by sensor 23.

FIG. 3F shows an example of an image that may be formed on and detected by the sensor 23, using the target of FIG. 3E in the apparatus of FIG. 3A, using the aperture plates 13NW or 13SE from FIG. 3D. While the sensor 19 cannot resolve the different individual periodic structures 32 to 35, the sensor 23 can do so. The dark rectangle represents the field of the image on the sensor, within which the illuminated spot 31 on the substrate is imaged into a corresponding circular area 41. Within this, rectangular areas 42-45 represent the images of the periodic structures 32 to 35. The target can be positioned in among device product features, rather than or in addition to in a scribe lane. If the periodic structures are located in device product areas, device features may also be visible in the periphery of this image field. Processor and controller PU processes these images using pattern recognition to identify the separate images 42 to 45 of periodic structures 32 to 35. In this way, the images do not have to be aligned very precisely at a specific location within the sensor frame, which greatly improves throughput of the measuring apparatus as a whole.

Once the separate images of the periodic structures have been identified, the intensities of those individual images can be measured, e.g., by averaging or summing selected pixel intensity values within the identified areas. Intensities and/or other properties of the images can be compared with one another. These results can be combined to measure different parameters of the lithographic process. Overlay performance is an example of such a parameter.

In a manufacturing process, variations in various process parameters (also referred to as “geometric parameters”) may have significant impact on the design of a suitable metrology target (or an alignment target) to faithfully reflect a device design. Such process parameters that may alter the metrology target or alignment target may include, but are not limited to, side-wall angle (determined by e.g. the etching or development process), refractive index (of a device layer or a resist layer), thickness (of a device layer or a resist layer), frequency of incident radiation, etch depth, floor tilt, extinction coefficient for the radiation source, coating asymmetry (for a resist layer or a device layer), variation in erosion during a chemical-mechanical polishing process, and the like. Computational techniques may also be used to define a metrology target for use in, e.g., a metrology system MET, through a metrology system simulation or in a target manufacturing process simulation (e.g., including exposing the metrology target using a lithographic process, developing the metrology target, etching the target, etc.). An example software platform used to design a metrology target includes a design for control (referred to as “DFC”), which is described below in detail. In a similar manner, an alignment target may be defined. A metrology target design or alignment target design may be characterized by various parameters. For the metrology target these parameters may be, for example, target coefficient (TC), stack sensitivity (SS), overlay impact (OV), or the like. Stack sensitivity may be understood as a measurement of how much the intensity of the signal changes as e.g., overlay changes because of diffraction between target (e.g., grating) layers. Target coefficient may be understood as a measurement of signal-to-noise ratio for a particular measurement time as a result of variations in photon collection by the measurement system. In an embodiment, the target coefficient may also be thought of as the ratio of stack sensitivity to photon noise; that is, the signal (i.e., the stack sensitivity) may be divided by a measurement of the photon noise to determine the target coefficient. Overlay impact measures the change in overlay error as a function of target design.

The metrology target design layout may specify one or more design parameters (e.g., geometric dimensions) for the target and further discrete values or a range of values may be specified for the one or more design parameters. Furthermore, a user and/or the system may impose one or more constraints on one or more design parameters (e.g., a relationship between pitch and trench width, a limit on pitch or trench width, a relationship between CD and pitch (e.g., CD is less than pitch), etc.) either in the same layer or between layers, based on, e.g., the lithographic process for which the target is desired. The one or more constraints may alternatively be on the one or more design parameters for which discrete values or a range has been specified, or on one or more other design parameters. The potential metrology target designs or alignment target designs may be input to a simulation to determine, for example, the viability and/or suitability of one or more of the target designs. The constraints may comprise a metrology parameter constraint. For example, in some metrology systems, the physics of the system may place a constraint (e.g., a wavelength of radiation used in the system may constrain the pitch of the target design). Alternatively, the constraint may be a process parameter constraint (e.g., a constraint dependent on etch type, development type, resist type, etc.). The terms ‘target’, ‘target grating’ and ‘target structure’ as used herein do not require that the structure has been provided specifically for the measurement being performed. Targets may comprise gratings, e.g., used in diffraction measurement techniques, but also other target types may be used such as box-in-box image based overlay targets. The metrology targets may be used to determine overlay, CD, focus, dose, etc., and a metrology target design layout may be defined using a data structure such as a pixel-based data structure or a polygon-based data structure. The polygon-based data structure may, for example, be described using GDSII data formats, which are rather common in the chip manufacturing industry. Still, any suitable data structure or data format may be used without departing from the scope of the embodiments.

As described above, a metrology target design platform, such as DFC, may be used in designing the metrology targets. In a DFC method, individual steps of a lithography process are modeled into a single process sequence to simulate the physical substrate processing. That process sequence drives the creation of the device geometry as a whole, rather than “building” the device geometry element-by-element. In some embodiments, the DFC methodology may be an advanced computer aided design (CAD) tool for automated generation of metrology targets. An arbitrary number of metrology targets can be designed in an efficient manner (e.g., with zero or minimal manual intervention), once the lithography process sequence is modeled and added as an input. The number of metrology targets can be in the thousands or even in the millions. The lithography process model takes into account characteristics of a lithography apparatus. DFC enables a user to be able to perform steps to design metrology targets without intervention from the creator of the DFC program. Appropriate graphic user interfaces (GUI) are made available to set up, execute, review and use the features of the DFC program. Usually, no special interface with the fabrication tools may be needed because the metrology target design is mostly confined in the simulation domain rather than in the actual device manufacturing domain.

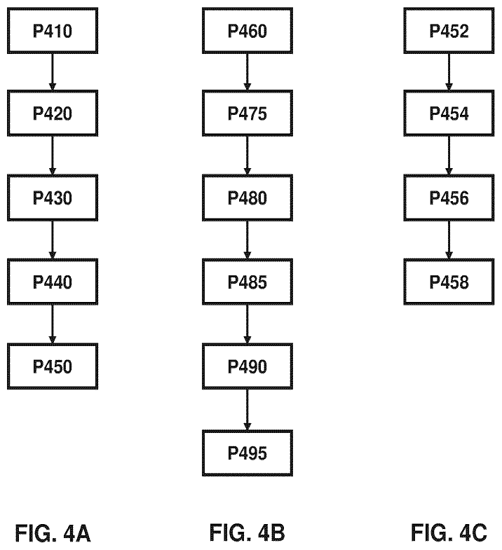

FIG. 4A shows a flowchart that lists the main stages of the DFC method. In process P410, the materials to be used in the lithography process are selected. The materials may be selected from a materials library interfaced with DFC through an appropriate GUI. In process P420, a lithography process is defined by entering each of the process steps, and building a computer simulation model for the entire process sequence. In process P430, a metrology target is defined, e.g., dimensions and other characteristics of various features included in the target are entered into the DFC program. For example, if a grating is included in a structure, then the number of grating elements, width of individual grating elements, spacing between two grating elements etc. have to be defined. In process P440, the 3D geometry is created. This step also takes into account if there is any information relevant to a multi-layer target design, for example, the relative shifts between different layers. This feature enables multi-layer target design. In process P450, the final geometry of the designed target is visualized. As will be explained in greater detail below, not only the final design is visualized, but as the designer applies various steps of the lithography process, he/she can visualize how the 3D geometry is being formed and changed because of process-induced effects. For example, the 3D geometry after resist patterning is different from the 3D geometry after resist removal and etching.

An important aspect of the present disclosure is that the target designer is enabled to visualize the stages of the method to facilitate their perception and control during modeling and simulation. Different visualization tools, referred to as “viewers,” are built into the DFC software. For example, as shown in FIG. 4B, a designer can view material plots P460 (and may also get a run time estimation plot) depending on the defined lithography process and target. Once the lithography model is created, the designer can view the model parameters through model viewer tool P475. Design layout viewer tool P480 may be used to view the design layout (e.g., visual rendering of the GDS file). Resist profile viewer tool P485 may be used to view pattern profiles in a resist. Geometry viewer tool P490 may be used to view 3D structures on a wafer. A pupil viewer tool P495 may be used to view simulated response on a metrology tool. Persons skilled in the art would understand that these viewing tools are available to enhance the understanding of the designer during design and simulation. One or more of these tools may not be present in some embodiments of DFC software, and additional viewing tools may be there in some other embodiments.

FIG. 4C shows a flow chart that illustrates how the DFC process increases efficiency in the overall simulation process by reducing the number of metrology targets selected for the actual simulation of the lithography process. As mentioned before, DFC enables designers to design thousands or even millions of designs. Not all of these designs may be robust against variations in the process steps. To select a subset of target designs that can withstand process variation, a lithographer may intentionally perturb one or more steps of the defined lithography process, as shown in block P452. The introduction of the perturbation alters the entire process sequence with respect to how it was originally defined. Therefore, applying the perturbed process sequence (block P454) alters the 3D geometry of the designed target too. A lithographer only selects the perturbations that show nonzero alternations in the original design targets and creates a subset of selected process perturbations (block P456). The lithography process is then simulated with this subset of process perturbations (block P458).

In designing a metrology mark, conventional methods may account for geometric parameters to be uniform for the metrology mark, and fail to account for intra-mark geometry variations or surrounding patterns. However, measurements obtained from such a metrology mark may be inaccurate as the variation of geometric parameters of the individual patterns (e.g., caused due to fabrication process variation), or a presence or absence of surrounding patterns, may have a significant bearing on the measurement performance of the mark.

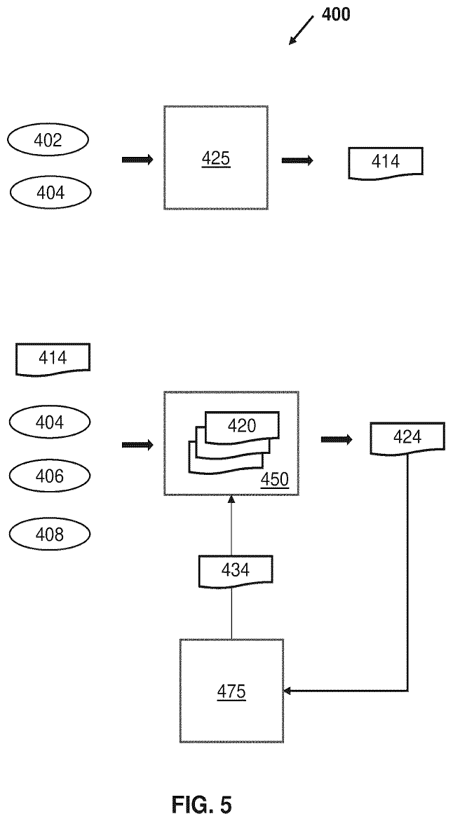

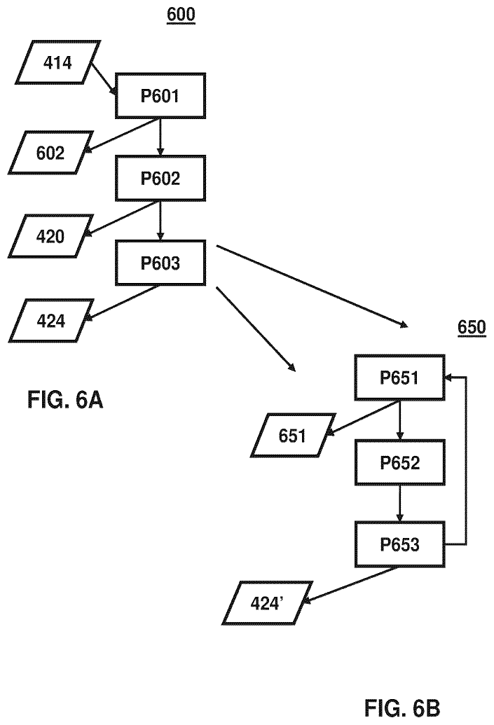

The following paragraphs describe designing a mark (e.g., a metrology mark) based on a local geometry of the mark at least with reference to FIGS. 5 and 6A-6B.

FIG. 5 is a block diagram of an exemplary system 400 for designing a mark based on the local geometry of the mark, in accordance with an embodiment of the present disclosure. FIG. 6A is a flow diagram an exemplary method 600 for designing a mark based on the local geometry of the mark, in accordance with an embodiment. The local geometry of the mark may be characterized by one or more of a spatial variation of geometric parameters, within or around the mark, a spatial location of the mark, or surrounding patterns of the mark.

At process P601, a mark design component 450 obtains a mark construction 602 of a specified mark. In some embodiments, the specified mark may include a metrology mark (e.g., an optical metrology mark), such as the target T of FIG. 3E. In some embodiments, a mark construction 602 may be associated with a spatial location 406 of the specified mark in a target design layout 414 and a mark design layout 408. The spatial location 406 and the mark design layout 408 may be provided as an input to the mark design component 450, e.g., by a user or by any other means. The target design layout 414 may correspond to a design layout for a full chip (e.g., IC), which includes a final geometry design of a number of marks (e.g., the specified mark being one of them). The target design layout 414 includes a 3D construction of the marks for the whole chip.

In some embodiments, the target design layout 414 may be generated by a full-chip design component 425, which may be implemented using one or more prediction models, such as using a process described with reference to FIG. 4A. In some embodiments, the full-chip design component 425 may take as input a full-chip design layout 402 and lithographic process information 404 as input to generate the target design layout 414. The full-chip design layout 402 may be in the form of a polygon-based data structure which, for example, includes a design of the marks as polygons and is described using GDSII data formats. The lithographic process information 404 include various parameters that are descriptive of a lithographic process, such as one or more of lithographic apparatus settings; materials used in lithographic process; stack information such as number of layers, thickness of the layer, etch depth, etc.; user-specified design constraints, such as CD, pitch, etc., process information; or process variation.

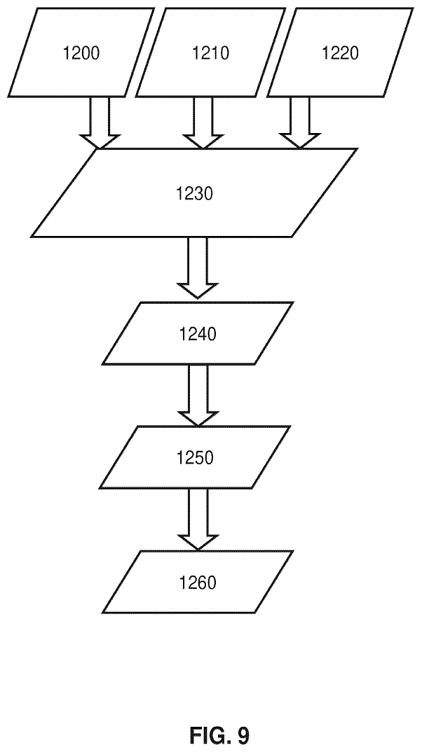

At process P602, the mark design component 450 obtains a spatial variation 420 of a geometric parameter associated with the mark construction. In some embodiments, the geometric parameter includes layer thickness t(x,y), a chemical mechanical polishing dishing height d(x,y), an etch sidewall angle a(x,y), a litho-etch CD bias b(x,y), an etch floor tilt s(x,y), or other such geometrical parameter associated with a lithographic process. In some embodiments, the mark design component 450 obtains the spatial variation 420 of the geometric parameters within specified mark. In some embodiments, such a geometric parameter may vary among the patterns. In some embodiment, such a geometric parameter may vary within an individual pattern. For example, if the specified mark has a number of periodic structures, such as the four periodic structures (gratings) 32-35 of mark T of FIG. 3E, then the mark design component 450 may obtain the spatial variation 420 of the geometric parameter for each pattern in each of the four periodic structures. In some embodiments, the spatial variation 420 is a distribution of the geometric parameter over a range of co-ordinates (e.g., (x1, y1) to (x2, y2)) corresponding to the coordinates of a pattern in the specified mark. In some embodiments, the spatial variation of the geometric parameters may be obtained from measurement data, empirical data, or experimental data. It may also be obtained by using models simulating the lithographic processes, such as the models described at least with reference to FIG. 9; an etch model, a deposition model or other related models that are configured to determine etch pattern, deposition pattern and respective pattern's characteristic values (e.g., CD, pattern placement error (PPE), edge placement error (EPE), etc.); a CMP model that is configured to model a residue; a development model for simulating a resist development process of a resist layer to obtain a characteristic of the development of the resist layer, or other models. A model can be a machine learning (ML) model, or a non-ML model (e.g., a physical model, an empirical model, a semi-empirical model).

In some embodiments, the mark design component 450 may determine the geometric parameters based on the target design layout 414 (e.g., generated by full-chip design component 425). For example, the mark design component 450 may extract the geometric parameters by identifying a grid in the target design layout 414 in which the specified mark is located, based on the spatial location 406 of the specified mark, and then obtain the spatial variation 420 of the geometrical parameters within the identified grid. In some embodiments, the size of the grid (e.g., area) is larger than the size of the specified mark. Since the grid size is larger than the specified mark, the mark design component 450 may interpolate the grid (e.g., using known interpolation methods) to obtain the geometrical parameters within the specified mark. The geometric parameters may vary among the individual patterns in the mark. Additionally, the mark design component 450 may also obtain information regarding surrounding patterns. For example, the information may include a presence or absence of patterns (e.g., metrology marks or device patterns) within a specified proximity of the specified mark. In some embodiments, the presence of surrounding patterns may have a significant bearing on the measurement performance of the mark, and therefore, the mark design component 450 may use the surrounding pattern information in designing the specified mark.

At process P603, the mark design component 450 generates a mark design 424, which is a 3D construction of the specified mark, based on the spatial variation 420 of the geometric parameters. In some embodiments, generating the mark design 424 includes determining geometry design of individual patterns of the specified mark based on the spatial variation 420 of the geometric parameters. The geometry design includes one or more of a CD, pitch, or sub-segmentation of the individual patterns of the specified mark. While the mark design 424 is generated based on the spatial variation 420 of the geometric parameters, the mark design component 450 may also consider surrounding patterns of the specified mark or a spatial location of the specified mark in generating or optimizing the mark design 424. Such a mark design 424, which is designed based on a local geometry of the mark (e.g., the spatial variation 420 of the geometric parameter for each pattern of the individual patterns in the mark, surrounding patterns of the specified mark or a spatial location of the specified mark), has a better measurement performance (better measurement accuracy) compared to the marks which are designed using conventional methods that do not consider a local geometry of the mark. In some embodiments, generating the mark design 424 may include simulating a measurement performance of the specified mark and adjusting a design of the mark iteratively until the measurement performance satisfied a threshold performance, as illustrated in FIG. 6B.

FIG. 6B is a flow diagram of an exemplary method 650 of optimizing a mark design, in accordance with an embodiment. In some embodiments, the method 650 is executed as part of the process P603 of the method 600 of FIG. 6A. At process P651, the mark design component 450 computes a cost function 651 that is representative of a key performance indicator (KPI), which in turn is indicative of a measurement performance (e.g., optical measurement performance) of the specified mark. In some embodiments, the mark design component 450 may compute the cost function 651 using a sensor prediction simulation process or a model 475 that predicts a measurement performance of the mark (e.g., measurements that may actually be obtained using the sensors of a metrology tool). As described above, the model 475 may simulate a measurement process performed by a sensing system installed on a metrology tool that is independent of or separate from a processing apparatus, or installed on a processing apparatus, e.g., a photo-lithography apparatus. For example, the mark design component 450 may input mark design 424 (e.g., the geometry design of the specified mark) to the sensor prediction model 475, which upon execution, simulates optical measurement parameters 434 that may be obtained from the metrology tool from measuring the specified mark. In some embodiments, the optical measurements 434 may include the intensity, wavelength and/or phase of radiation (e.g., of a source of the metrology apparatus of FIG. 3A), a pupil size, amount of radiation in the pupil, etc. The mark design component 450 may generate one or more KPIs based on the optical measurements 434. For example, one KPI may be a swing curve or a color to color bias, which is a difference between measurements obtained using different source wavelengths. The mark design component 450 may then compute the cost function 651 based on the optical measurement parameters (e.g., for a particular KPI).

At process P652, in some embodiments, the mark design component 450 determines whether a termination condition is satisfied. In some embodiments, the termination condition is satisfied when the cost function 651 is minimized or maximized. For example, if the cost function is a KPI such as color to color bias, then the termination condition is satisfied when the cost function 651 is minimized (or is below a threshold value). In some embodiments, when the termination condition is satisfied, a measurement performance of the mark design 424 is treated as satisfactory, and the method 650 may conclude by outputting the mark design 424. However, if the termination condition is not satisfied (e.g., cost function 651 is not minimized or maximized), the mark design component 450 may proceed to process P653 to adjust the mark design 424.

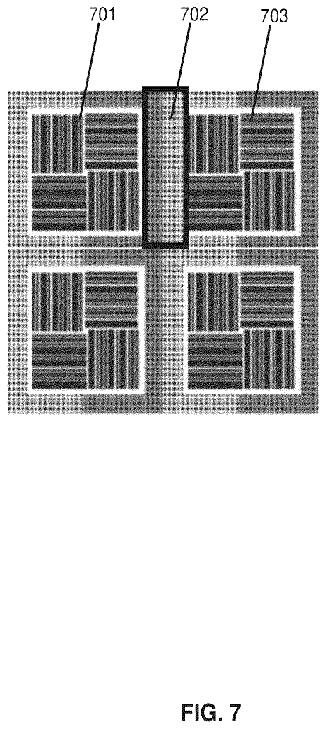

At process P653, the mark design component 450 adjusts the mark design 424 to generate an adjusted mark design 424′. In some embodiments, adjusting the mark design 424 includes adjusting the geometry design such as at least one of a CD, pitch, or sub-segmentation of the patterns of the specified mark. The adjustment may or may not differ among the individual patterns of the mark. In some embodiments, adjusting the geometry design includes adjusting the spatial location of the specified mark (e.g., changing the spatial location of the specified mark in the target design layout 414). In some embodiments, adjusting the geometry design includes adding or adjusting a mark in an empty space between two marks (e.g., to minimize optical crosstalk or lithographic process challenges due to empty spaces; this process is usually referred to as “dummification”). For example, as illustrated in FIG. 7, the mark design component 450 may add a mark in the empty space 702 between a first mark 701 and a second mark 703.

The optimization method 650 may be an iterative process and may be executed iteratively until a termination condition is satisfied. In some embodiments, the termination condition is satisfied when (a) the cost function 651 is minimized or maximized, (b) method 650 (e.g., operations P651-P653) is executed for a predefined number of iterations, or (c) other such condition. After the method 650 concludes, the control may be transferred to process P603 of method 600, which outputs the adjusted mark design 424′ as the mark design 424.

While the foregoing paragraphs describe the embodiments being implemented for designing or optimizing a mark, the embodiments may also be implemented for monitoring measurements made using a given mark in addition to, or instead of, optimizing the given mark. For example, after reconstructing a mark design of the given mark based on a local geometry of the mark (e.g., as described in process P603 of method 600 and without any optimization to the geometry design of the mark), the mark design component 450 may generate one or more KPIs based on optical measurements simulated by the sensor prediction model 475 for the given mark. The mark design component 450 may then determine a difference between the KPI and a threshold value of the KPI (e.g., the value at which the given mark is considered to be optimized). This difference (e.g., may be calculated as a percentage) may be determined as an amount of correction to be applied to any actual measurements obtained (from a metrology tool) using the mark in order to obtain accurate measurements. For example, if the actual KPI determined based on the measurements obtained using the mark is X, and the correction to the KPI is determined as +Y %, then the mark design component 450 may output the corrected KPI as X±Y %.

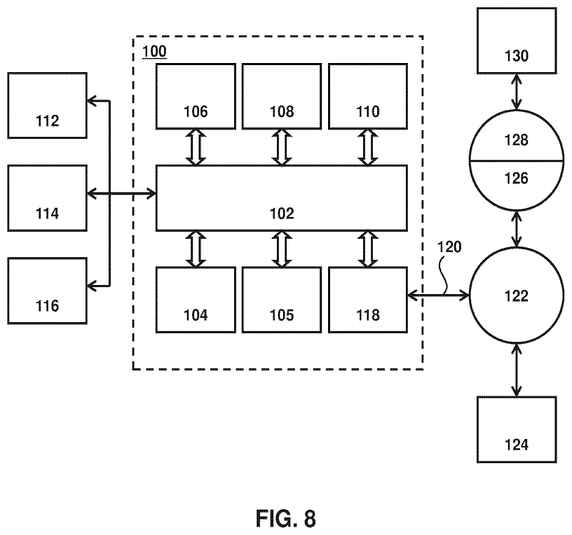

FIG. 8 is a block diagram that illustrates a computer system 100 which can assist in implementing the systems and methods disclosed herein. Computer system 100 includes a bus 102 or other communication mechanism for communicating information, and a processor 104 (or multiple processors 104 and 105) coupled with bus 102 for processing information. Computer system 100 also includes a main memory 106, such as a random access memory (RAM) or other dynamic storage device, coupled to bus 102 for storing information and instructions to be executed by processor 104. Main memory 106 also may be used for storing temporary variables or other intermediate information during execution of instructions to be executed by processor 104. Computer system 100 further includes a read only memory (ROM) 108 or other static storage device coupled to bus 102 for storing static information and instructions for processor 104. A storage device 110, such as a magnetic disk or optical disk, is provided and coupled to bus 102 for storing information and instructions.

Computer system 100 may be coupled via bus 102 to a display 112, such as a cathode ray tube (CRT) or flat panel or touch panel display for displaying information to a computer user. An input device 114, including alphanumeric and other keys, is coupled to bus 102 for communicating information and command selections to processor 104. Another type of user input device is cursor control 116, such as a mouse, a trackball, or cursor direction keys for communicating direction information and command selections to processor 104 and for controlling cursor movement on display 112. This input device typically has two degrees of freedom in two axes, a first axis (e.g., x) and a second axis (e.g., y), that allows the device to specify positions in a plane. A touch panel (screen) display may also be used as an input device.

According to one embodiment, portions of the optimization process may be performed by computer system 100 in response to processor 104 executing one or more sequences of one or more instructions contained in main memory 106. Such instructions may be read into main memory 106 from another computer-readable medium, such as storage device 110. Execution of the sequences of instructions contained in main memory 106 causes processor 104 to perform the process steps described herein. One or more processors in a multi-processing arrangement may also be employed to execute the sequences of instructions contained in main memory 106. In an alternative embodiment, hard-wired circuitry may be used in place of or in combination with software instructions. Thus, the description herein is not limited to any specific combination of hardware circuitry and software.

The term “computer-readable medium” as used herein refers to any medium that participates in providing instructions to processor 104 for execution. Such a medium may take many forms, including but not limited to, non-volatile media, volatile media, and transmission media. Non-volatile media include, for example, optical or magnetic disks, such as storage device 110. Volatile media include dynamic memory, such as main memory 106. Transmission media include coaxial cables, copper wire and fiber optics, including the wires that comprise bus 102. Transmission media can also take the form of acoustic or light waves, such as those generated during radio frequency (RF) and infrared (IR) data communications. Common forms of computer-readable media include, for example, a floppy disk, a flexible disk, hard disk, magnetic tape, any other magnetic medium, a CD-ROM, DVD, any other optical medium, punch cards, paper tape, any other physical medium with patterns of holes, a RAM, a PROM, and EPROM, a FLASH-EPROM, any other memory chip or cartridge, a carrier wave as described hereinafter, or any other medium from which a computer can read.

Various forms of computer readable media may be involved in carrying one or more sequences of one or more instructions to processor 104 for execution. For example, the instructions may initially be borne on a magnetic disk of a remote computer. The remote computer can load the instructions into its dynamic memory and send the instructions over a telephone line using a modem. A modem local to computer system 100 can receive the data on the telephone line and use an infrared transmitter to convert the data to an infrared signal. An infrared detector coupled to bus 102 can receive the data carried in the infrared signal and place the data on bus 102. Bus 102 carries the data to main memory 106, from which processor 104 retrieves and executes the instructions. The instructions received by main memory 106 may optionally be stored on storage device 110 either before or after execution by processor 104.

Computer system 100 also preferably includes a communication interface 118 coupled to bus 102. Communication interface 118 provides a two-way data communication coupling to a network link 120 that is connected to a local network 122. For example, communication interface 118 may be an integrated services digital network (ISDN) card or a modem to provide a data communication connection to a corresponding type of telephone line. As another example, communication interface 118 may be a local area network (LAN) card to provide a data communication connection to a compatible LAN. Wireless links may also be implemented. In any such implementation, communication interface 118 sends and receives electrical, electromagnetic or optical signals that carry digital data streams representing various types of information.

Network link 120 typically provides data communication through one or more networks to other data devices. For example, network link 120 may provide a connection through local network 122 to a host computer 124 or to data equipment operated by an Internet Service Provider (ISP) 126. ISP 126 in turn provides data communication services through the worldwide packet data communication network, now commonly referred to as the “Internet” 128. Local network 122 and Internet 128 both use electrical, electromagnetic or optical signals that carry digital data streams. The signals through the various networks and the signals on network link 120 and through communication interface 118, which carry the digital data to and from computer system 100, are exemplary forms of carrier waves transporting the information.

Computer system 100 can send messages and receive data, including program code, through the network(s), network link 120, and communication interface 118. In the Internet example, a server 130 might transmit a requested code for an application program through Internet 128, ISP 126, local network 122 and communication interface 118. One such downloaded application may provide for the illumination optimization of the embodiment, for example. The received code may be executed by processor 104 as it is received, and/or stored in storage device 110, or other non-volatile storage for later execution. In this manner, computer system 100 may obtain application code in the form of a carrier wave.

An exemplary flow chart for modelling and/or simulating parts of a patterning process is illustrated in FIG. 9. As will be appreciated, the models may represent a different patterning process and need not comprise all the models described below. A source model 1200 represents optical characteristics (including radiation intensity distribution, bandwidth and/or phase distribution) of the illumination of a patterning device. The source model 1200 can represent the optical characteristics of the illumination that include, but not limited to, numerical aperture settings, illumination sigma (σ) settings as well as any particular illumination shape (e.g., off-axis radiation shape such as annular, quadrupole, dipole, etc.), where σ (or sigma) is outer radial extent of the illuminator.

A projection optics model 1210 represents optical characteristics (including changes to the radiation intensity distribution and/or the phase distribution caused by the projection optics) of the projection optics. The projection optics model 1210 can represent the optical characteristics of the projection optics, including aberration, distortion, one or more refractive indexes, one or more physical sizes, one or more physical dimensions, etc.

The patterning device/design layout model module 1220 captures how the design features are laid out in the pattern of the patterning device and may include a representation of detailed physical properties of the patterning device, as described, for example, in U.S. Pat. No. 7,587,704, which is incorporated by reference in its entirety. In an embodiment, the patterning device/design layout model module 1220 represents optical characteristics (including changes to the radiation intensity distribution and/or the phase distribution caused by a given design layout) of a design layout (e.g., a device design layout corresponding to a feature of an integrated circuit, a memory, an electronic device, etc.), which is the representation of an arrangement of features on or formed by the patterning device. Since the patterning device used in the lithographic projection apparatus can be changed, it is desirable to separate the optical properties of the patterning device from the optical properties of the rest of the lithographic projection apparatus including at least the illumination and the projection optics. The objective of the simulation is often to accurately predict, for example, edge placements and CDs, which can then be compared against the device design. The device design is generally defined as the pre-OPC patterning device layout, and will be provided in a standardized digital file format such as GDSII or OASIS.

An aerial image 1230 can be simulated from the source model 1200, the projection optics model 1210 and the patterning device/design layout model module 1220. An aerial image (AI) is the radiation intensity distribution at substrate level. Optical properties of the lithographic projection apparatus (e.g., properties of the illumination, the patterning device and the projection optics) dictate the aerial image.

A resist layer on a substrate is exposed by the aerial image and the aerial image is transferred to the resist layer as a latent “resist image” (RI) therein. The resist image (RI) can be defined as a spatial distribution of solubility of the resist in the resist layer. A resist image 1250 can be simulated from the aerial image 1230 using a resist model 1240. The resist model can be used to calculate the resist image from the aerial image, an example of which can be found in U.S. Patent Application Publication No. US 2009-0157360, the disclosure of which is hereby incorporated by reference in its entirety. The resist model typically describes the effects of chemical processes which occur during resist exposure, post exposure bake (PEB) and development, in order to predict, for example, contours of resist features formed on the substrate and so it typically related only to such properties of the resist layer (e.g., effects of chemical processes which occur during exposure, post-exposure bake and development). In an embodiment, the optical properties of the resist layer, e.g., refractive index, film thickness, propagation and polarization effects—may be captured as part of the projection optics model 1210.

So, in general, the connection between the optical and the resist model is a simulated aerial image intensity within the resist layer, which arises from the projection of radiation onto the substrate, refraction at the resist interface and multiple reflections in the resist film stack. The radiation intensity distribution (aerial image intensity) is turned into a latent “resist image” by absorption of incident energy, which is further modified by diffusion processes and various loading effects. Efficient simulation methods that are fast enough for full-chip applications approximate the realistic 3-dimensional intensity distribution in the resist stack by a 2-dimensional aerial (and resist) image.

In an embodiment, the resist image can be used an input to a post-pattern transfer process model module 1260. The post-pattern transfer process model module 1260 defines performance of one or more post-resist development processes (e.g., etch, development, etc.).

Simulation of the patterning process can, for example, predict contours, CDs, edge placement (e.g., edge placement error), etc. in the resist and/or etched image. Thus, the objective of the simulation is to accurately predict, for example, edge placement, and/or aerial image intensity slope, and/or CD, etc. of the printed pattern. These values can be compared against an intended design to, e.g., correct the patterning process, identify where a defect is predicted to occur, etc. The intended design is generally defined as a pre-OPC design layout which can be provided in a standardized digital file format such as GDSII or OASIS or other file format.

Thus, the model formulation describes most, if not all, of the known physics and chemistry of the overall process, and each of the model parameters desirably corresponds to a distinct physical or chemical effect. The model formulation thus sets an upper bound on how well the model can be used to simulate the overall manufacturing process.

While the concepts disclosed herein may be used for imaging on a substrate such as a silicon wafer, it shall be understood that the disclosed concepts may be used with any type of lithographic imaging systems, e.g., those used for imaging on substrates other than silicon wafers.

The terms “optimizing” and “optimization” as used herein refers to or means adjusting a patterning apparatus (e.g., a lithography apparatus), a patterning process, etc. such that results and/or processes have more desirable characteristics, such as higher accuracy of projection of a design pattern on a substrate, a larger process window, etc. Thus, the term “optimizing” and “optimization” as used herein refers to or means a process that identifies one or more values for one or more parameters that provide an improvement, e.g., a local optimum, in at least one relevant metric, compared to an initial set of one or more values for those one or more parameters. “Optimum” and other related terms should be construed accordingly. In an embodiment, optimization steps can be applied iteratively to provide further improvements in one or more metrics.

Aspects of the invention can be implemented in any convenient form. For example, an embodiment may be implemented by one or more appropriate computer programs which may be carried on an appropriate carrier medium which may be a tangible carrier medium (e.g., a disk) or an intangible carrier medium (e.g., a communications signal). Embodiments of the invention may be implemented using suitable apparatus which may specifically take the form of a programmable computer running a computer program arranged to implement a method as described herein. Thus, embodiments of the disclosure may be implemented in hardware, firmware, software, or any combination thereof. Embodiments of the disclosure may also be implemented as instructions stored on a machine-readable medium, which may be read and executed by one or more processors. A machine-readable medium may include any mechanism for storing or transmitting information in a form readable by a machine (e.g., a computing device). For example, a machine-readable medium may include read only memory (ROM); random access memory (RAM); magnetic disk storage media; optical storage media; flash memory devices; electrical, optical, acoustical or other forms of propagated signals (e.g., carrier waves, infrared signals, digital signals, etc.), and others. Further, firmware, software, routines, instructions may be described herein as performing certain actions. However, it should be appreciated that such descriptions are merely for convenience and that such actions in fact result from computing devices, processors, controllers, or other devices executing the firmware, software, routines, instructions, etc.

Embodiments of the present disclosure may be further described by the following clauses.

1. A non-transitory computer-readable medium having instructions that, when executed by a computer, cause the computer to execute a method for a mark design for use in imaging of a pattern on a substrate using a lithographic process in a lithographic apparatus, the method comprising:
obtaining a mark construction;
obtaining a spatial variation of a geometric parameter associated with the mark construction, wherein the spatial variation is associated with a lithographic process; and
determining geometry design of individual patterns of a mark based on the spatial variation of the mark.

2. The computer-readable medium of clause 1, wherein the geometry design is further determined based on surrounding patterns of the mark.

3. The computer-readable medium of clause 1, wherein determining the geometry design includes determining at least one of a critical dimension, pitch, or sub-segmentation of the individual patterns of the mark.

4. The computer-readable medium of clause 1, wherein determining the geometry design includes determining the spatial location of the mark in a target design to be printed on the substrate.

5. The computer-readable medium of clause 1, wherein determining the geometry design includes iteratively adjusting the geometry design based on predicted measurement performance.

6. The computer-readable medium of clause 5, wherein each iteration includes:
(i) computing a cost function;
(ii) determining whether the cost function satisfies the specified condition; and
(iii) adjusting the geometry design based on a determination that the cost function does not satisfy the specified condition.

7. The computer-readable medium of clause 5, wherein the iteratively adjusting the geometry design includes adjusting at least one of a critical dimension, pitch, or sub-segmentation of the individual patterns of the mark, or adjusting the spatial location of the mark.

8. The computer-readable medium of clause 5, wherein adjusting the geometry design includes adding or adjusting one or more patterns surrounding the mark.

9. The computer-readable medium of clause 5, wherein the cost function includes one or more performance indicators that are indicative of the optical measurement performance of the mark.

10. The computer-readable medium of clause 5, wherein computing the cost function includes: inputting the geometry design of the mark to a first simulation model, the first simulation model configured to simulate optical measurement parameters obtained using the mark from a measurement tool that is configured to measure a pattern printed on the substrate;
executing the first simulation model to obtain the optical measurement parameters; and
computing the cost function based on the optical measurement parameters.

11. The computer-readable medium of clause 1 further comprising:
determining the geometry design of individual patterns of the mark based on a spatial location of the mark.

12. The computer-readable medium of clause 1, wherein the mark construction comprises multiple patterns and each pattern is characterized by a critical dimension, pitch, or sub-segmentation of the individual patterns.

13. The computer-readable medium of clause 1, wherein obtaining the mark construction includes:
inputting a target design layout and design layout variables of the lithographic process to a second simulation model that is configured to generate a three-dimensional (3D) representation of a design corresponding to the target design layout printed on the substrate using the lithographic process; and
executing the second simulation model to obtain simulation results, the simulation results including the 3D representation of the design.

14. The computer-readable medium of clause 13, wherein obtaining the spatial variation of the geometric parameter includes:
identifying, in the target design layout, a grid having the mark, wherein a size of the grid is greater than a size of the mark; and
obtaining, from the simulation results, the spatial variation of the geometric parameter on the grid.

15. The computer-readable medium of clause 14, wherein obtaining the spatial variation includes interpolating the grid to obtain spatial variation of the geometrical parameter for each of the individual patterns of the mark.

16. The computer-readable medium of clause 14, wherein determining the geometry design includes:
reconstructing, using the simulation model, the individual patterns of the mark based on the spatial variation of the geometric parameter and a mark design layout.

17. The computer-readable medium of clause 16, wherein the individual patterns are further reconstructed based on a characteristic of surrounding patterns of the mark.

18. The computer-readable medium of clause 1, wherein the spatial variation of the geometric parameter is obtained using at least one of measurement data, empirical data, experimental or data.

19. The computer-readable medium of clause 1, wherein the geometric parameter includes at least one of a layer thickness, a chemical mechanical polishing dishing height, an etch sidewall angle, a litho-etch critical dimension bias, or an etch floor tilt.

20. The computer-readable medium of clause 1, wherein the geometric parameter varies within an individual pattern.

21. The computer-readable medium of clause 1 further comprising:
obtaining, using a first simulation model, a measurement performance of the mark;
performing a measurement using a measurement tool to obtain a measurement signal, the measurement signal including a set of optical measurement parameters obtained using the mark; and
adjusting the measurement signal based on the measurement performance.

22. The computer-readable medium of clause 1, wherein the mark includes at least one of a metrology mark, an overlay mark or an alignment mark.

23. The computer-readable medium of clause 1 further comprising:
generating a mask pattern based on the mark, the mask pattern including patterns corresponding to a target design layout to be printed on the substrate.

24. The computer-readable medium of clause 23 further comprising:
performing a patterning step using the mask pattern to print the patterns on the substrate via the lithographic process.

25. A computer-implemented method for a mark design for use in imaging of a pattern on a substrate using a lithographic process in a lithographic apparatus, the method comprising:
obtaining a mark construction;
obtaining a spatial variation of a geometric parameter associated with the mark construction, wherein the spatial variation is associated with a lithographic process; and
determining geometry design of individual patterns of a mark based on the spatial variation of the mark.

26. The method of clause 25, wherein the geometry design is further determined based on surrounding patterns of the mark.

27. The method of clause 25, wherein determining the geometry design includes determining at least one of a critical dimension, pitch, or sub-segmentation of the individual patterns of the mark.

28. The method of clause 25, wherein determining the geometry design includes determining the spatial location of the mark in a target design to be printed on the substrate.

29. The method of clause 25, wherein determining the geometry design includes iteratively adjusting the geometry design based on predicted measurement performance.

30. The method of clause 29, wherein each iteration includes:
(iv) computing a cost function;
(v) determining whether the cost function satisfies the specified condition; and
(vi) adjusting the geometry design based on a determination that the cost function does not satisfy the specified condition.

31. The method of clause 29, wherein the iteratively adjusting the geometry design includes adjusting at least one of a critical dimension, pitch, or sub-segmentation of the individual patterns of the mark, or adjusting the spatial location of the mark.

32. The method of clause 29, wherein adjusting the geometry design includes adding or adjusting one or more patterns surrounding the mark.

33. The method of clause 29, wherein the cost function includes one or more performance indicators that are indicative of the optical measurement performance of the mark.

34. The method of clause 29, wherein computing the cost function includes:
inputting the geometry design of the mark to a first simulation model, the first simulation model configured to simulate optical measurement parameters obtained using the mark from a measurement tool that is configured to measure a pattern printed on the substrate;
executing the first simulation model to obtain the optical measurement parameters; and
computing the cost function based on the optical measurement parameters.

35. The method of clause 25 further comprising:
determining the geometry design of individual patterns of the mark based on a spatial location of the mark.

36. The method of clause 25, wherein the mark construction comprises multiple patterns and each pattern is characterized by a critical dimension, pitch, or sub-segmentation of the individual patterns.

37. The method of clause 25, wherein obtaining the mark construction includes:
inputting a target design layout and design layout variables of the lithographic process to a second simulation model that is configured to generate a three-dimensional (3D) representation of a design corresponding to the target design layout printed on the substrate using the lithographic process; and
executing the second simulation model to obtain simulation results, the simulation results including the 3D representation of the design.

38. The method of clause 37, wherein obtaining the spatial variation of the geometric parameter includes:
identifying, in the target design layout, a grid having the mark, wherein a size of the grid is greater than a size of the mark; and
obtaining, from the simulation results, the spatial variation of the geometric parameter on the grid.

39. The method of clause 38, wherein obtaining the spatial variation includes interpolating the grid to obtain spatial variation of the geometrical parameter for each of the individual patterns of the mark.

40. The method of clause 38, wherein determining the geometry design includes:
reconstructing, using the simulation model, the individual patterns of the mark based on the spatial variation of the geometric parameter and a mark design layout.

41. The method of clause 40, wherein the individual patterns are further reconstructed based on a characteristic of surrounding patterns of the mark.

42. The method of clause 25, wherein the spatial variation of the geometric parameter is obtained using at least one of measurement data, empirical data, experimental or data.

43. The method of clause 25, wherein the geometric parameter includes at least one of a layer thickness, a chemical mechanical polishing dishing height, an etch sidewall angle, a litho-etch critical dimension bias, or an etch floor tilt.

44. The method of clause 25, wherein the geometric parameter varies within an individual pattern.

45. The method of clause 25 further comprising:
obtaining, using a first simulation model, a measurement performance of the mark;
performing a measurement using a measurement tool to obtain a measurement signal, the measurement signal including a set of optical measurement parameters obtained using the mark; and
adjusting the measurement signal based on the measurement performance.

46. The method of clause 25, wherein the mark includes at least one of a metrology mark, an overlay mark or an alignment mark.

47. The method of clause 25 further comprising:
generating a mask pattern based on the mark, the mask pattern including patterns corresponding to a target design layout to be printed on the substrate.

48. The method of clause 47 further comprising:
performing a patterning step using the mask pattern to print the patterns on the substrate via the lithographic process.

49. An apparatus for improving imaging of a feature on a mask to a substrate during a scanning operation of a lithographic apparatus, the apparatus comprising:
a memory storing a set of instructions; and
a processor configured to execute the set of instructions to cause the apparatus to perform a method of:
   obtaining a mark construction;
   obtaining a spatial variation of a geometric parameter associated with the mark construction, wherein the spatial variation is associated with a lithographic process; and
   determining geometry design of individual patterns of a mark based on the spatial variation of the mark.

In block diagrams, illustrated components are depicted as discrete functional blocks, but embodiments are not limited to systems in which the functionality described herein is organized as illustrated. The functionality provided by each of the components may be provided by software or hardware modules that are differently organized than is presently depicted, for example such software or hardware may be intermingled, conjoined, replicated, broken up, distributed (e.g., within a data center or geographically), or otherwise differently organized. The functionality described herein may be provided by one or more processors of one or more computers executing code stored on a tangible, non-transitory, machine readable medium. In some cases, third party content delivery networks may host some or all of the information conveyed over networks, in which case, to the extent information (e.g., content) is said to be supplied or otherwise provided, the information may be provided by sending instructions to retrieve that information from a content delivery network.

Unless specifically stated otherwise, as apparent from the discussion, it is appreciated that throughout this specification discussions utilizing terms such as “processing,” “computing,” “calculating,” “determining” or the like refer to actions or processes of a specific apparatus, such as a special purpose computer or a similar special purpose electronic processing/computing device.

The reader should appreciate that the present application describes several inventions. Rather than separating those inventions into multiple isolated patent applications, these inventions have been grouped into a single document because their related subject matter lends itself to economies in the application process. But the distinct advantages and aspects of such inventions should not be conflated. In some cases, embodiments address all of the deficiencies noted herein, but it should be understood that the inventions are independently useful, and some embodiments address only a subset of such problems or offer other, unmentioned benefits that will be apparent to those of skill in the art reviewing the present disclosure. Due to costs constraints, some inventions disclosed herein may not be presently claimed and may be claimed in later filings, such as continuation applications or by amending the present claims. Similarly, due to space constraints, neither the Abstract nor the Summary sections of the present document should be taken as containing a comprehensive listing of all such inventions or all aspects of such inventions.

It should be understood that the description and the drawings are not intended to limit the present disclosure to the particular form disclosed, but to the contrary, the intention is to cover all modifications, equivalents, and alternatives falling within the spirit and scope of the inventions as defined by the appended claims.

Modifications and alternative embodiments of various aspects of the inventions will be apparent to those skilled in the art in view of this description. Accordingly, this description and the drawings are to be construed as illustrative only and are for the purpose of teaching those skilled in the art the general manner of carrying out the inventions. It is to be understood that the forms of the inventions shown and described herein are to be taken as examples of embodiments. Elements and materials may be substituted for those illustrated and described herein, parts and processes may be reversed or omitted, certain features may be utilized independently, and embodiments or features of embodiments may be combined, all as would be apparent to one skilled in the art after having the benefit of this description. Changes may be made in the elements described herein without departing from the spirit and scope of the invention as described in the following claims. Headings used herein are for organizational purposes only and are not meant to be used to limit the scope of the description.

As used throughout this application, the word “may” is used in a permissive sense (i.e., meaning having the potential to), rather than the mandatory sense (i.e., meaning must). The words “include”, “including”, and “includes” and the like mean including, but not limited to. As used throughout this application, the singular forms “a,” “an,” and “the” include plural referents unless the content explicitly indicates otherwise. Thus, for example, reference to “an” element or “a” element includes a combination of two or more elements, notwithstanding use of other terms and phrases for one or more elements, such as “one or more.” As used herein, unless specifically stated otherwise, the term “or” encompasses all possible combinations, except where infeasible. For example, if it is stated that a component may include A or B, then, unless specifically stated otherwise or infeasible, the component may include A, or B, or A and B. As a second example, if it is stated that a component may include A, B, or C, then, unless specifically stated otherwise or infeasible, the component may include A, or B, or C, or A and B, or A and C, or B and C, or A and B and C.

Terms describing conditional relationships, e.g., “in response to X, Y,” “upon X, Y,”, “if X, Y,” “when X, Y,” and the like, encompass causal relationships in which the antecedent is a necessary causal condition, the antecedent is a sufficient causal condition, or the antecedent is a contributory causal condition of the consequent, e.g., “state X occurs upon condition Y obtaining” is generic to “X occurs solely upon Y” and “X occurs upon Y and Z.” Such conditional relationships are not limited to consequences that instantly follow the antecedent obtaining, as some consequences may be delayed, and in conditional statements, antecedents are connected to their consequents, e.g., the antecedent is relevant to the likelihood of the consequent occurring. Statements in which a plurality of attributes or functions are mapped to a plurality of objects (e.g., one or more processors performing steps A, B, C, and D) encompasses both all such attributes or functions being mapped to all such objects and subsets of the attributes or functions being mapped to subsets of the attributes or functions (e.g., both all processors each performing steps A-D, and a case in which processor 1 performs step A, processor 2 performs step B and part of step C, and processor 3 performs part of step C and step D), unless otherwise indicated. Further, unless otherwise indicated, statements that one value or action is “based on” another condition or value encompass both instances in which the condition or value is the sole factor and instances in which the condition or value is one factor among a plurality of factors. Unless otherwise indicated, statements that “each” instance of some collection have some property should not be read to exclude cases where some otherwise identical or similar members of a larger collection do not have the property, i.e., each does not necessarily mean each and every. References to selection from a range includes the end points of the range.

In the above description, any processes, descriptions or blocks in flowcharts should be understood as representing modules, segments or portions of code which include one or more executable instructions for implementing specific logical functions or steps in the process, and alternate implementations are included within the scope of the exemplary embodiments of the present advancements in which functions can be executed out of order from that shown or discussed, including substantially concurrently or in reverse order, depending upon the functionality involved, as would be understood by those skilled in the art.

To the extent certain U.S. patents, U.S. patent applications, or other materials (e.g., articles) have been incorporated by reference, the text of such U.S. patents, U.S. patent applications, and other materials is only incorporated by reference to the extent that no conflict exists between such material and the statements and drawings set forth herein. In the event of such conflict, any such conflicting text in such incorporated by reference U.S. patents, U.S. patent applications, and other materials is specifically not incorporated by reference herein.

While certain embodiments have been described, these embodiments have been presented by way of example only, and are not intended to limit the scope of the present disclosures. Indeed, the novel methods, apparatuses and systems described herein can be embodied in a variety of other forms; furthermore, various omissions, substitutions and changes in the form of the methods, apparatuses and systems described herein can be made without departing from the spirit of the present disclosures. The accompanying claims and their equivalents are intended to cover such forms or modifications as would fall within the scope and spirit of the present disclosures.

1. A method for a mark design for use in imaging of a pattern on a substrate using a lithographic process in a lithographic apparatus, the method comprising:
obtaining a mark construction;
obtaining a spatial variation of a geometric parameter associated with the mark construction, wherein the spatial variation is associated with a lithographic process; and
determining, by a hardware computer, a geometry design of individual patterns of a mark based on the spatial variation of the mark.

2. The method of claim 1, wherein the geometry design is further determined based on surrounding patterns of the mark.

3. The method of claim 1, wherein determining the geometry design includes determining at least one selected from: a critical dimension, pitch, or sub-segmentation, of the individual patterns of the mark.

4. The method of claim 1, wherein determining the geometry design includes iteratively adjusting the geometry design based on predicted measurement performance.

5. The method of claim 4, wherein each iteration includes:
computing a cost function;
determining whether the cost function satisfies a specified condition; and
adjusting the geometry design based on a determination that the cost function does not satisfy the specified condition.

6. The method of claim 5, wherein the cost function includes one or more performance indicators that are indicative of the optical measurement performance of the mark.

7. The method of claim 1, wherein obtaining the mark construction includes:
inputting a target design layout and design layout variables of the lithographic process to a simulation model that is configured to generate a three-dimensional (3D) representation of a design corresponding to the target design layout printed on the substrate using the lithographic process; and
executing the simulation model to obtain simulation results, the simulation results including the 3D representation of the design.

8. The method of claim 1, wherein obtaining the spatial variation of the geometric parameter includes:
identifying, in the target design layout, a grid having the mark, wherein a size of the grid is greater than a size of the mark; and
obtaining, from the simulation results, the spatial variation of the geometric parameter on the grid.

9. The method of claim 8, wherein obtaining the spatial variation includes interpolating the grid to obtain spatial variation of the geometrical parameter for each of the individual patterns of the mark.

10. The method of claim 1, wherein determining the geometry design includes reconstructing, using a simulation model, the individual patterns of the mark based on the spatial variation of the geometric parameter and a mark design layout.

11. The method of claim 10, wherein the individual patterns are further reconstructed based on a characteristic of surrounding patterns of the mark.

12. The method of claim 1, wherein the spatial variation of the geometric parameter is obtained using at least one selected from: of measurement data, empirical data, or experimental data, and wherein the geometric parameter includes at least one selected from: a layer thickness, a chemical mechanical polishing dishing height, an etch sidewall angle, a litho-etch critical dimension bias, or an etch floor tilt.

13. The method of claim 1, wherein the geometric parameter varies within an individual pattern.

14. The method of claim 1 further comprising:
obtaining, using a first simulation model, a measurement performance of the mark;
performing a measurement using a measurement tool to obtain a measurement signal, the measurement signal including a set of optical measurement parameters obtained using the mark; and
adjusting the measurement signal based on the measurement performance.

15. The method of claim 1, wherein the mark includes at least one selected from: a metrology mark, an overlay mark or an alignment mark, and further comprising generating a mask pattern based on the mark, the mask pattern including patterns corresponding to a target design layout to be printed on the substrate.

16. The method of claim 1, wherein determining the geometry design includes determining a spatial location of the mark in a target design to be printed on the substrate.

17. A computer program product comprising a non-transitory computer-readable medium comprising instructions therein, the instructions, when executed by one or more processors, are configured to cause the one or more processors to at least:
obtain a spatial variation of a geometric parameter associated with a mark construction, wherein the spatial variation is associated with a lithographic process in a lithographic apparatus; and
determine a geometry design of individual patterns of a mark based on the spatial variation of the mark, the design for use in imaging of a pattern on a substrate using the lithographic process.

18. The computer program product of claim 17, wherein the geometry design is further determined based on surrounding patterns of the mark.

19. The computer program product of claim 17, wherein the instructions configured to cause the one or more processors to determine the geometry design are further configured to cause the one or more processors to determine at least one selected from: a critical dimension, pitch, or sub-segmentation, of the individual patterns of the mark.

20. The computer program product of claim 17, wherein the instructions configured to cause the one or more processors to determine the geometry design are further configured to cause the one or more processors to iteratively adjust the geometry design based on predicted measurement performance.
